(19) United States
(12) Patent Application Publication
(10) Pub. No.: US 2025/0246439 A1
(43) Pub. Date: Jul. 31, 2025

(54) SEMICONDUCTOR OPTICAL DEVICE AND METHOD OF MANUFACTURING THE SAME

(71) Applicant: SUMITOMO ELECTRIC INDUSTRIES, LTD., Osaka (JP)

(72) Inventors: Naoko INOUE, Osaka-shi (JP); Takehiko KIKUCHI, Osaka-shi (JP); Naoki FUJIWARA, Osaka-shi (JP)

(73) Assignee: SUMITOMO ELECTRIC INDUSTRIES, LTD., Osaka (JP)

(21) Appl. No.: 18/975,524

(22) Filed: Dec. 10, 2024

(30) Foreign Application Priority Data
Jan. 31, 2024 (JP) 2024-013054

(51) Int. Cl. H01L 21/324; H01L 21/02; H01L 25/16

(52) U.S. Cl. CPC H01L 21/3245; H01L 21/02126; H01L 25/167

(57) ABSTRACT

A method of manufacturing a semiconductor optical device is a method of manufacturing a semiconductor optical device including a substrate having a silicon layer and a semiconductor element having a III-V group compound semiconductor layer. The silicon layer is provided with a waveguide, a terrace, and an outgassing countermeasure structure, and the outgassing countermeasure structure includes a portion recessed from an upper surface of the silicon layer. The method includes bringing the semiconductor element into contact with the upper surface of the silicon layer by disposing the semiconductor element over the waveguide and the outgassing countermeasure structure, and bonding the semiconductor element to the substrate by performing a thermal treatment after the bringing into contact.

### CROSS REFERENCE TO RELATED APPLICATIONS

This application claims priority based on Japanese Patent Application No. 2024-013054 filed on Jan. 31, 2024, and the entire contents of the Japanese patent application are incorporated herein by reference.

### TECHNICAL FIELD

The present disclosure relates to a semiconductor optical device and a method of manufacturing the same.

### BACKGROUND ART

There is known a technique for bonding a semiconductor element formed of a compound semiconductor and having an optical gain to a substrate such as a silicon on insulator (SOI) substrate (silicon photonics) in which a waveguide is formed. After the semiconductor element is brought into contact with the substrate, a thermal treatment is performed to bond the semiconductor element. The temperature in the thermal treatment is about several hundred degrees. Moisture and the like are vaporized by the thermal treatment, resulting in the generation of outgas. The outgas bulges at the bonding interface and voids are generated, thereby reducing the bonding strength. The outgas in the voids may expand, causing the semiconductor element to burst. A technique of providing a structure for releasing outgas from the interface in the SOI substrate has been developed (for example, non-patent literature: D. Liang, J. E. Bowers “Highly efficient vertical outgassing channels for low-temperature InP-to-silicon direct wafer bonding on the silicon-on-insulator substrate”, Journal of Vacuum Science & Technology B: Microelectronics and Nanometer Structures Processing, Measurement, and Phenomena 26, 1560 (2008)).

### SUMMARY OF THE INVENTION

A method of manufacturing a semiconductor optical device according to the present disclosure is a method of manufacturing a semiconductor optical device including a substrate having a silicon layer and a semiconductor element having a III-V group compound semiconductor layer. The silicon layer is provided with a waveguide, a terrace, and an outgassing countermeasure structure, and the outgassing countermeasure structure includes a portion recessed from an upper surface of the silicon layer. The method includes bringing the semiconductor element into contact with the upper surface of the silicon layer by disposing the semiconductor element over the waveguide and the outgassing countermeasure structure, and bonding the semiconductor element to the substrate by performing a thermal treatment after the bringing into contact.

### BRIEF DESCRIPTION OF THE DRAWINGS

FIG. 1 is a plan view illustrating a silicon wafer.

FIG. 2A is a plan view illustrating a semiconductor optical device according to a first embodiment.

FIG. 2B is a plan view illustrating a substrate.

FIG. 3 is a cross-sectional view illustrating a semiconductor optical device.

FIG. 4A is an enlarged view of recessed portions.

FIG. 4B is a cross-sectional view illustrating a recessed portion.

FIG. 4C is an enlarged view of recessed portions.

FIG. 5A is a plan view illustrating a method of manufacturing a semiconductor optical device.

FIG. 5B is a cross-sectional view illustrating a method of manufacturing a semiconductor optical device.

FIG. 5C is a cross-sectional view illustrating a method of manufacturing a semiconductor optical device.

FIG. 5D is a cross-sectional view illustrating a method of manufacturing a semiconductor optical device.

FIG. 6A is a plan view illustrating a method of manufacturing a semiconductor optical device.

FIG. 6B is a cross-sectional view illustrating a method of manufacturing a semiconductor optical device.

FIG. 7A is a plan view illustrating a method of manufacturing a semiconductor optical device.

FIG. 7B is a cross-sectional view illustrating a method of manufacturing a semiconductor optical device.

FIG. 8A is a plan view illustrating a method of manufacturing a semiconductor optical device.

FIG. 8B is a cross-sectional view illustrating a method of manufacturing a semiconductor optical device.

FIG. 9A is a plan view illustrating a method of manufacturing a semiconductor optical device.

FIG. 9B is a cross-sectional view illustrating a method of manufacturing a semiconductor optical device.

FIG. 10 is a cross-sectional view illustrating a method of manufacturing a semiconductor optical device according to a first modification.

FIG. 11A is a plan view illustrating a recessed portion according to a second modification.

FIG. 11B is a plan view illustrating a recessed portion according to a second modification.

FIG. 11C is a plan view illustrating a recessed portion according to a second modification.

FIG. 12 is a plan view illustrating a substrate according to a second embodiment.

FIG. 13A is a plan view illustrating a method of manufacturing a semiconductor optical device.

FIG. 13B is a plan view illustrating a method of manufacturing a semiconductor optical device.

FIG. 14A is a plan view illustrating a substrate according to a third embodiment.

FIG. 14B is a plan view illustrating a method of manufacturing a semiconductor optical device.

### DETAILED DESCRIPTION

In the step after the bonding, outgas may be generated and voids may be formed. Thus, it is an object of the present disclosure to provide a semiconductor optical device capable of suppressing the generation of voids due to outgas and a method of manufacturing the same.

### DESCRIPTION OF EMBODIMENTS OF PRESENT DISCLOSURE

First, the contents of embodiments of the present disclosure will be listed and explained.

(1) A method of manufacturing a semiconductor optical device according to an aspect of the present disclosure is a method of manufacturing a semiconductor optical device including a substrate having a silicon layer and a semiconductor element having a III-V group compound semiconductor layer. The silicon layer is provided with a waveguide, a terrace, and an outgassing countermeasure structure, and the outgassing countermeasure structure includes a portion recessed from an upper surface of the silicon layer. The method includes bringing the semiconductor element into contact with the upper surface of the silicon layer by disposing the semiconductor element over the waveguide and the outgassing countermeasure structure, and bonding the semiconductor element to the substrate by performing a thermal treatment after the bringing into contact. Outgas is generated in the bonding step. The outgas enters the outgassing countermeasure structure. The generation of voids due to the outgas can be suppressed.

(2) In the above (1), the outgassing countermeasure structure may include a first recessed portion, and in the bringing into contact, the first recessed portion may be located under the semiconductor element. Since the outgas is confined in the first recessed portion, the generation of voids can be suppressed.

(3) In the above (2), a planar shape of the first recessed portion may be ring-shaped. The outgas is unlikely to be concentrated at one place inside the first recessed portion. Since the internal pressure of the first recessed portion is unlikely to increase, the generation of voids can be suppressed.

(4) In the above (2) or (3), the planar shape of the first recessed portion may include a curve. The outgas is unlikely to be concentrated at one place inside the first recessed portion. Since the internal pressure of the first recessed portion is unlikely to increase, the generation of voids can be suppressed.

(5) In any one of the above (2) to (4), the substrate may have the silicon layer and a box layer, the box layer may be provided on a surface of the silicon layer opposite to the upper surface, and a bottom surface of the first recessed portion may be formed by the silicon layer or the box layer. Since the outgas is confined in the first recessed portion, the generation of voids can be suppressed.

(6) In any one of the above (1) to (5), the outgassing countermeasure structure may include a second recessed portion, and in the bringing into contact, a first end portion of the second recessed portion may extend from under the semiconductor element to outside the semiconductor element. The outgas is discharged to the outside through the second recessed portion. The generation of voids can be suppressed.

(7) In the above (6), at least one end portion of the second recessed portion may be located under the semiconductor element and may have a curved shape. The outgas is unlikely to be concentrated at one place in the second recessed portion, and the internal pressure is unlikely to increase. The generation of voids can be suppressed.

(8) In the above (6) or (7), the substrate may have the silicon layer and a box layer, the box layer may be provided on a surface of the silicon layer opposite to the upper surface, and a bottom surface of the second recessed portion may be formed by the silicon layer. The box layer is protected by the silicon layer.

(9) A semiconductor optical device includes a substrate having a silicon layer, and a semiconductor element having a III-V group compound semiconductor layer. The silicon layer is provided with a waveguide, a terrace, and an outgassing countermeasure structure, the outgassing countermeasure structure includes a portion recessed from an upper surface of the silicon layer, and the semiconductor element is disposed over the waveguide and the outgassing countermeasure structure and bonded to the upper surface of the silicon layer. The outgas is generated in the bonding step. The outgas enters the outgassing countermeasure structure. The generation of voids due to the outgas can be suppressed.

### DETAILS OF EMBODIMENTS OF PRESENT DISCLOSURE

Specific examples of a semiconductor optical device and a method of manufacturing the same according to embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

### (Semiconductor Optical Device)

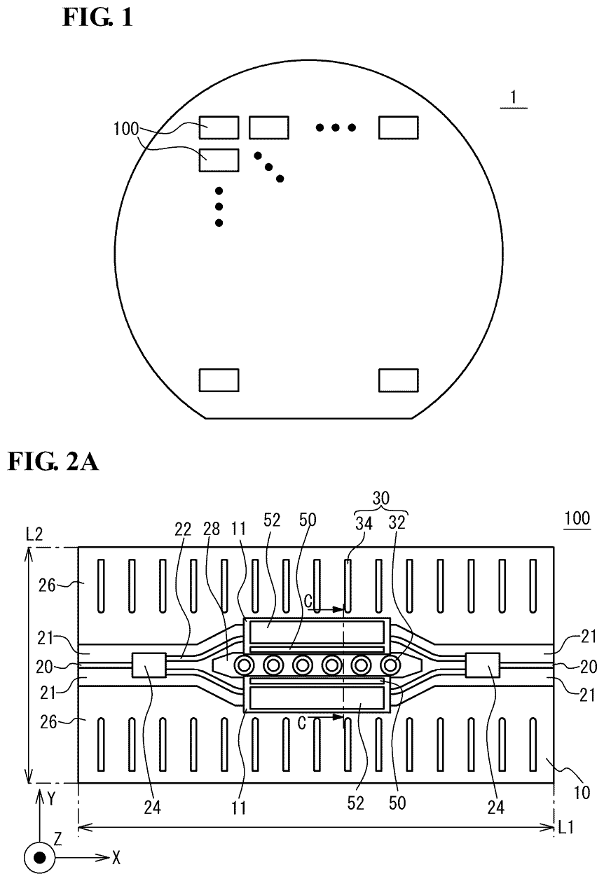

FIG. 1 is a plan view illustrating a silicon wafer. A plurality of semiconductor optical devices 100 are formed on a silicon wafer 1. By dicing silicon wafer 1, the plurality of semiconductor optical devices 100 are separated from each other.

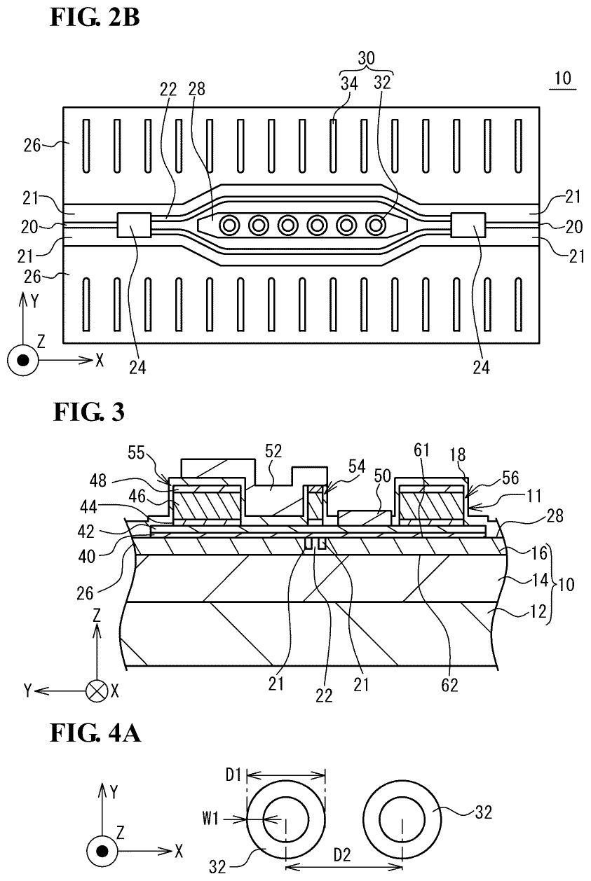

FIG. 2A is a plan view illustrating semiconductor optical device 100 according to the first embodiment, and illustrates one semiconductor optical device 100 in an enlarged manner. An insulating film covering the substrate and the like is seen through. As illustrated in FIG. 2A, semiconductor optical device 100 is a Mach-Zehnder modulator, and includes a substrate 10 and two semiconductor elements 11. Semiconductor element 11 is bonded to one surface of substrate 10. A Z-axis direction is a normal direction of an upper surface of substrate 10. Two sides of substrate 10 are parallel to an X-axis. The other two sides are parallel to a Y-axis. An X-axis direction, a Y-axis direction, and the Z-axis direction are orthogonal to each other. A length L1 of substrate 10 in the X-axis direction is, for example, 2 mm. A length L2 in the Y-axis direction is, for example, 1 mm.

FIG. 2B is a plan view illustrating substrate 10. Substrate 10 includes two waveguides 20, two waveguides 22, two multiplexing/demultiplexing devices 24, a terrace 26, a terrace 28, and an outgassing countermeasure structure 30. Waveguide 20, multiplexing/demultiplexing device 24, two waveguides 22, multiplexing/demultiplexing device 24, and waveguide 20 are arranged in this order in the X-axis direction. Multiplexing/demultiplexing device 24 is a 1×2 multi-mode interference (MMI).

One end of one waveguide 20 is optically coupled to one multiplexing/demultiplexing device 24. One end of each of two waveguides 22 is optically coupled to one multiplexing/demultiplexing device 24, and the other end of each of two waveguides 22 is coupled to the other multiplexing/demultiplexing device 24. The other waveguide 20 is coupled to the other multiplexing/demultiplexing device 24.

Terrace 26 is located on both sides of the waveguides in the Y-axis direction and are spaced apart from the waveguides. Terrace 28 is located between two waveguides 22. Terrace 26 and terrace 28 are flat portions of substrate 10. Recessed portions 21 are provided between the waveguide and terrace 26, and between the waveguide and terrace 28. A width of the waveguide in the Y-axis direction is, for example, 1 μm. A width of recessed portion 21 is, for example, 1 μm.

As illustrated in FIG. 2A, two semiconductor elements 11 are located over waveguide 22, terrace 26 and terrace 28. Semiconductor element 11 includes an electrode 50 and an electrode 52. A portion of semiconductor element 11 over waveguide 22 may have a tapered shape. The tapered portion is tapered along waveguide 22, thereby increasing the coupling efficiency.

Outgassing countermeasure structure 30 includes a plurality of recessed portions 32 (first recessed portion) and a plurality of recessed portions 34 (second recessed portion). Recessed portions 32 are provided in terrace 28. Recessed portions 34 are provided in terrace 26. Outgassing countermeasure structure 30 will be described later.

FIG. 3 is a cross-sectional view illustrating semiconductor optical device 100, illustrating a cross section taken along line C-C of FIG. 2A. The cross section includes semiconductor element 11. As illustrated in FIG. 3, substrate 10 is a silicon on insulator (SOI) substrate, and includes a substrate 12, a box layer 14, and a silicon (Si) layer 16, which are sequentially stacked in the Z-axis direction. Substrate 12 is formed of, for example, Si. Box layer 14 is formed of, for example, silicon oxide (SiO₂). A thickness of substrate 12 is, for example, 100 μm. A thickness of box layer 14 is, for example, 3 μm. A thickness of silicon layer 16 is, for example, 400 nm. Silicon layer 16 has a surface 61 (upper surface) and a surface 62 (lower surface). Semiconductor element 11 is bonded to surface 61. Surface 62 is a surface opposite to surface 61, and box layer 14 is provided on surface 62. The upper surface of substrate 10 is covered with an insulating film 18. Insulating film 18 is formed of, for example, SiO₂ with a thickness of 1 μm. A refractive index of silicon layer 16 is 3.45. A refractive index of each of box layer 14 and insulating film 18 is 1.45, which is lower than that of silicon layer 16.

Terrace 26 of silicon layer 16, waveguide 22, and terrace 28 are arranged from the left to right in FIG. 3. An upper surface of waveguide 22 is located at the same height as upper surfaces of terrace 26 and terrace 28. The upper surface of waveguide 22, the upper surface of terrace 26, and the upper surface of terrace 28 are located at the same height as surface 61 of silicon layer 16 in the Z-axis direction. Recessed portion 21 is recessed in the Z-axis direction compared to waveguide 22, terrace 26, and terrace 28. A depth of recessed portion 21 is, for example, 300 nm. Recessed portion 21 may extend partway into silicon layer 16, or may penetrate silicon layer 16 and extend to box layer 14.

Semiconductor element 11 includes a damage relaxation layer 40, a cladding layer 42, a core layer 44, a cladding layer 46, and a contact layer 48. Damage relaxation layer 40 is bonded to an upper surface of silicon layer 16 of substrate 10. On damage relaxation layer 40, cladding layer 42, core layer 44, cladding layer 46, and contact layer 48 are stacked in this order. Optical confinement layers (not illustrated) may be provided between core layer 44 and cladding layer 42, and between core layer 44 and cladding layer 46.

Semiconductor element 11 includes a mesa 54, a protruding portion 55, and a protruding portion 56. Protruding portion 55, mesa 54, and protruding portion 56 are arranged in this order from the left in FIG. 3. Protruding portion 55 is located above terrace 26. Protruding portion 56 is located above terrace 28. Mesa 54 is located above waveguide 22. Mesa 54 and the protruding portions each include core layer 44, cladding layer 46, and contact layer 48, and protrude from an upper surface of cladding layer 42 in the Z-axis direction. Mesa 54, protruding portion 55, and protruding portion 56 are spaced apart from each other.

Semiconductor element 11 is covered with insulating film 18. Insulating film 18 has openings above mesa 54 and between mesa 54 and protruding portion 56. Electrode 50 is provided between mesa 54 and protruding portion 56, and is in contact with cladding layer 42 exposed from the opening of insulating film 18, and is electrically connected to cladding layer 42. Electrode 52 extends from mesa 54 onto protruding portion 55. Electrode 52 is in contact with contact layer 48 of mesa 54, and is electrically connected to contact layer 48.

Damage relaxation layer 40 is formed of, for example, non-doped gallium indium arsenide phosphide (i-GaInAsP) having a thickness of 200 nm. The bandgap wavelength of damage relaxation layer 40 is 1.2 μm. Cladding layer 42 is formed of, for example, n-type indium phosphide (n-InP) having a thickness of 200 nm. The n-type semiconductor layer is doped with, for example, Si. The doping concentration in cladding layer 42 is, for example, 1×10¹⁹ cm⁻³. Cladding layer 46 is formed of, for example, p-type InP having a thickness of 1500 nm. Contact layer 48 is formed of, for example, (p+)-gallium indium arsenide (GaInAs) having a thickness of 200 nm. The p-type semiconductor layer is doped with, for example, zinc (Zn) or carbon (C). The doping concentration in cladding layer 46 is, for example, 1× 10¹⁸ cm⁻³. The doping concentration in contact layer 48 is, for example, 1× 10¹⁹ cm⁻³.

Core layer 44 includes a plurality of well layers and barrier layers alternately stacked, and has a multi quantum well (MQW) structure. The well layer and the barrier layer are formed of, for example, non-doped gallium indium arsenide phosphide (i-GaInAsP). A thickness of core layer 44 is, for example, 300 nm. A thickness of the well layer is, for example, 6 nm. A thickness of the barrier layer is, for example, 10 nm. Core layer 44 has an optical gain and emits light having a wavelength of 1.55 μm, for example. The optical confinement layer (not illustrated) is formed of, for example, i-GaInAsP having a thickness of 100 nm. The bandgap wavelength is, for example, 1.2 μm. Each layer of semiconductor element 11 may be a III-V group compound semiconductor layer other than the above.

Electrode 50 is formed of a metal such as an alloy of gold, germanium, and nickel (AuGeNi). Electrode 52 is, for example, a stacked body in which a titanium (Ti) layer, a platinum (Pt) layer, and an Au layer are stacked in order from a side close to substrate 10. Electrode 50 and electrode 52 may be provided with an Au plating layer or the like.

### (Outgassing Countermeasure Structure)

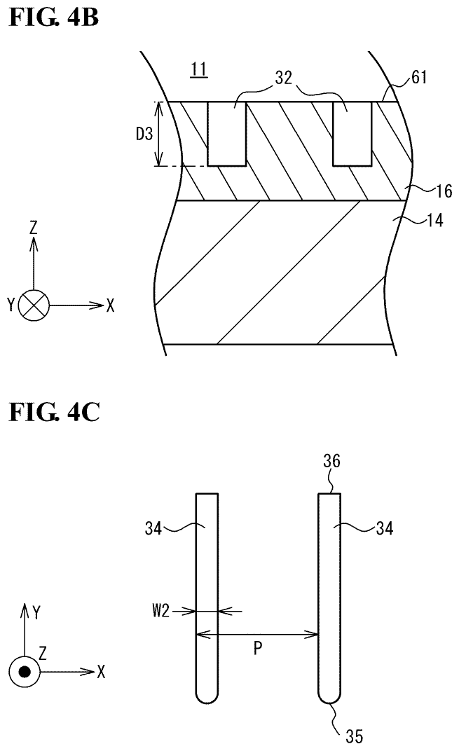

FIG. 4A is an enlarged view of recessed portions 32. A planar shape of recessed portion 32 is, for example, a circular ring. A width W1 of recessed portion 32 is, for example, 1 μm to 10 μm, and may be 5 μm. An outer diameter D1 of recessed portion 32 is, for example, 10 μm to 100 μm, and may be 50 μm. A plurality of recessed portions 32 are arranged in the X-axis direction. A distance (pitch) D2 between the centers of two adjacent recessed portions 32 is, for example, 100 μm to 200 μm.

FIG. 4B is a cross-sectional view illustrating recessed portion 32, illustrating box layer 14 and silicon layer 16 of substrate 10. Recessed portion 32 is recessed compared to surface 61 of silicon layer 16 and extends partway into silicon layer 16. A depth D3 of recessed portion 32 is, for example, 190 nm. The inside of recessed portion 32 is hollow.

FIG. 4C is an enlarged view of recessed portions 34. Recessed portion 34 is, for example, a groove parallel to the Y-axis. A width W2 of recessed portion 34 is, for example, 1 μm to 10 μm. A plurality of recessed portions 34 are arranged in the X-axis direction. A pitch P between recessed portions 34 is, for example, 100 μm to 200 μm. A depth of recessed portion 34 is, for example, 190 nm, the same as recessed portion 32. The inside of recessed portion 34 is hollow. An end portion 35 of recessed portion 34 in the Y-axis direction includes a curve, and has, for example, an arc shape. An end portion 36 has vertices.

Semiconductor element 11 and substrate 10 are evanescently optically coupled with each other. Light is made incident on one waveguide 20. The light is distributed to two waveguides 22 at multiplexing/demultiplexing device 24. The light is transferred to semiconductor element 11. The light is modulated by applying a voltage to electrode 50 and electrode 52. The modulated light is transferred to waveguide 22 and is emitted from the other waveguide 20.

### (Method of Manufacturing)

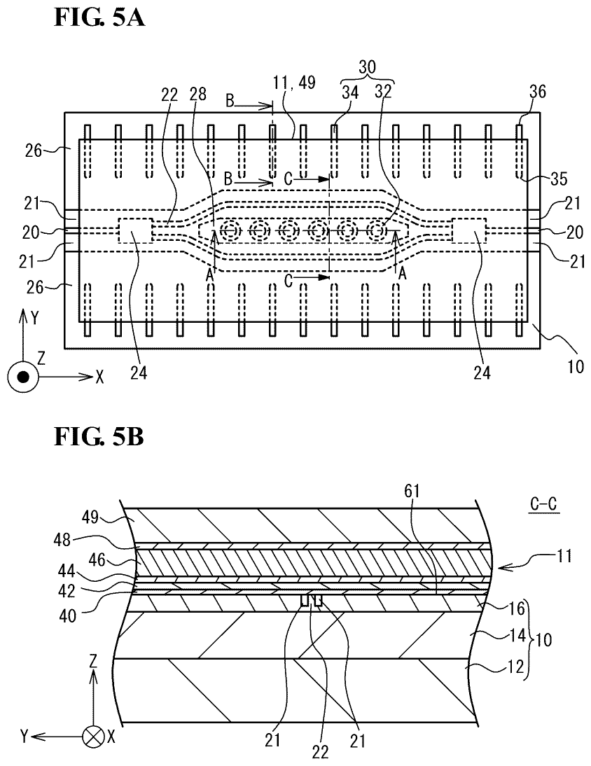

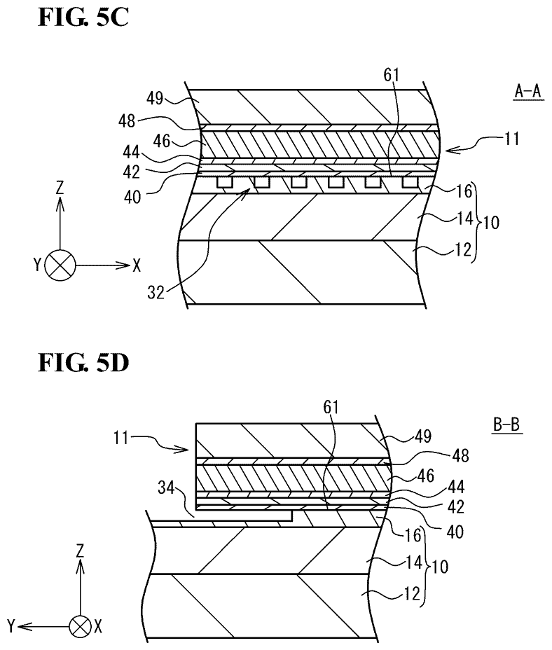

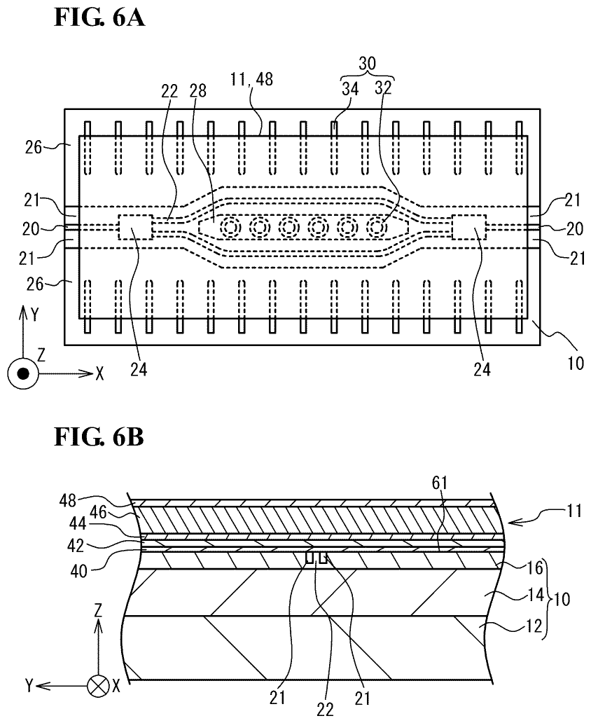

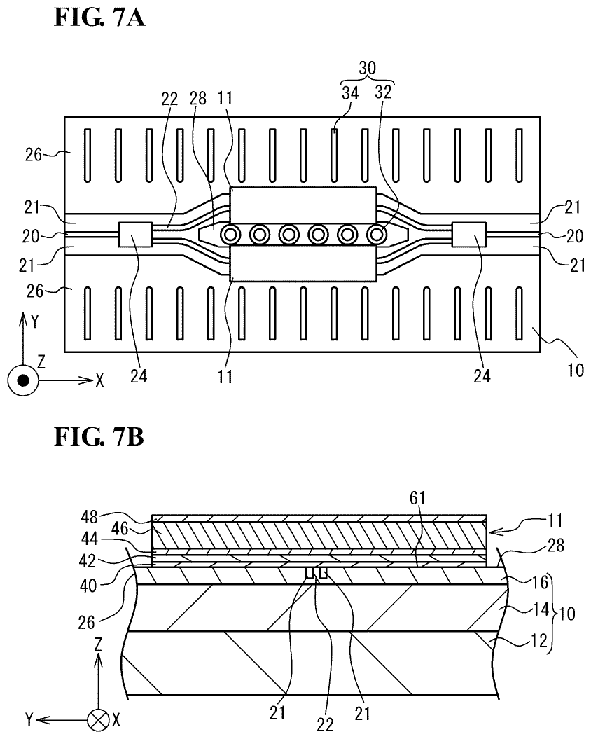

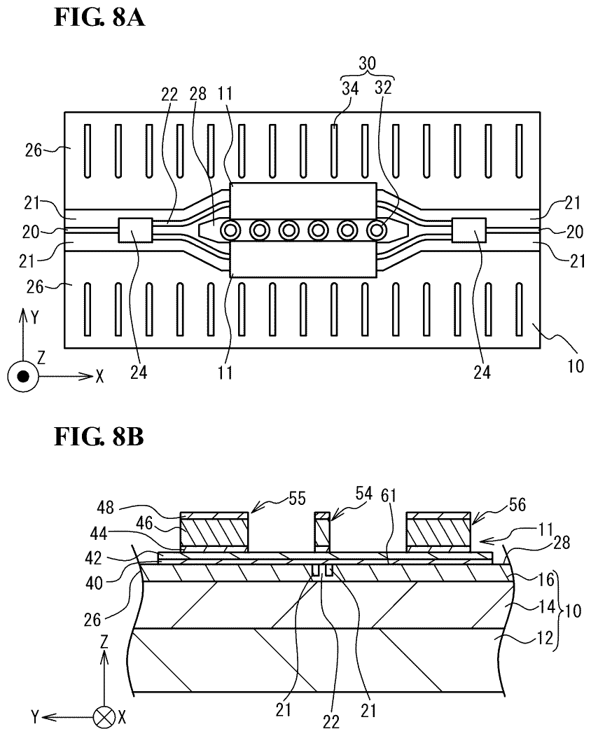

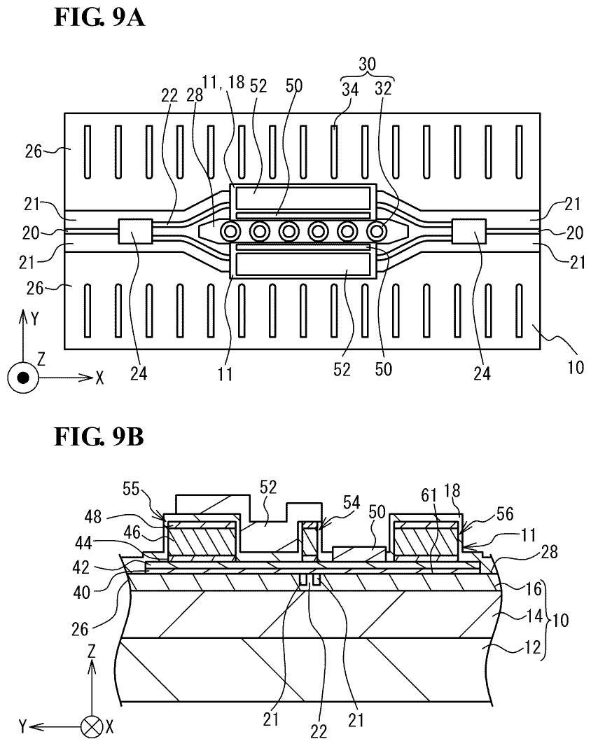

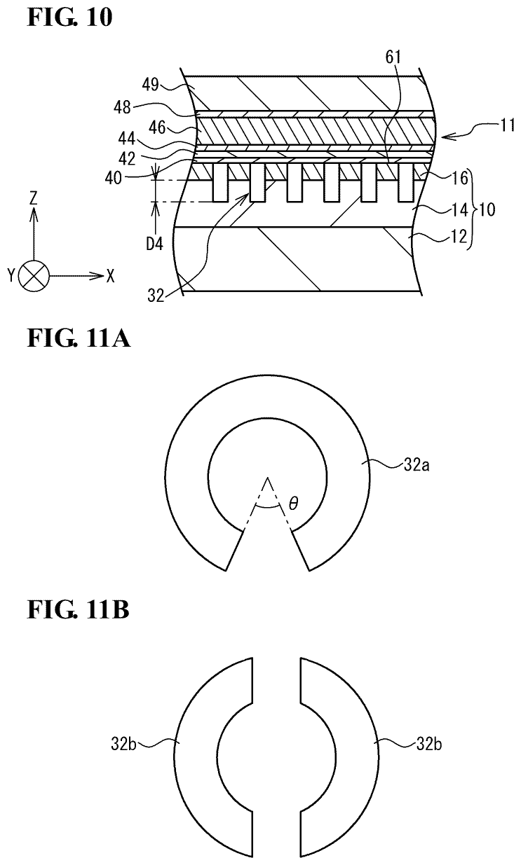

FIG. 5A, FIG. 6A, FIG. 7A, 8A, and FIG. 9A are plan views each illustrating a method of manufacturing semiconductor optical device 100. FIG. 5B to FIG. 5D, FIG. 6B, FIG. 7B, FIG. 8B, and FIG. 9B are cross-sectional views each illustrating a method of manufacturing semiconductor optical device 100. FIG. 5B, FIG. 6B, FIG. 7B, FIG. 8B and FIG. 9B are cross-sectional views at the position corresponding to FIG. 3.

Before semiconductor element 11 is bonded, dry etching is performed to silicon wafer 1 to form recessed portion 21, outgassing countermeasure structure 30, and the like. On a p-type indium phosphorus (p-InP) wafer, contact layer 48, cladding layer 46, core layer 44, cladding layer 42, and damage relaxation layer 40 are epitaxially grown in this order by organometal vapor-phase epitaxy (OMVPE) method. Damage relaxation layer 40 is located on a surface of the wafer. By cutting the wafer, a plurality of semiconductor elements 11 are manufactured.

As illustrated in FIG. 5A to FIG. 5D, semiconductor element 11 is bonded to substrate 10. A length of semiconductor element 11 in the X-axis direction is, for example, 1 mm to 2 mm. A length in the Y-axis direction is, for example, 0.5 mm. As illustrated in FIG. 5B, damage relaxation layer 40 is in contact with silicon layer 16. Semiconductor element 11 has an InP substrate 49 on contact layer 48.

In the bonding step, surface 61 of silicon layer 16 and a surface of damage relaxation layer 40 are activated and cleaned. The activation is performed by, for example, ultraviolet (UV) ozone treatment. The cleaning is performed with ultrasonic cleaning water. Damage relaxation layer 40 is brought into contact with surface 61 of silicon layer 16 at room temperature in the air to perform temporary bonding. After the temporary bonding, a thermal treatment is performed at 150° C. for about 2 hours, for example. Moisture is removed by the thermal treatment, enhancing the bonding strength.

By the thermal treatment, water molecules and carbon-based impurities, and the like may vaporize, resulting in the generation of outgas. There is a possibility that the outgas may enter the bonding interface and form voids (gaps). In the void, semiconductor element 11 is lifted from substrate 10, and the bonding strength is reduced. In the first embodiment, substrate 10 is provided with outgassing countermeasure structure 30.

FIG. 5C is a cross-sectional view taken along line A-A of FIG. 5A, illustrating a cross section including recessed portions 32. As illustrated in FIG. 5A and FIG. 5C, a plurality of recessed portions 32 are located under semiconductor element 11 and are sealed. The outgas enters recessed portion 32 and is confined in recessed portion 32. Thus, the generation of voids is suppressed. A planar shape of recessed portion 32 is a circular ring shape and has no vertex. Since the outgas is unlikely to be concentrated at one place in recessed portion 32, pressure is unlikely to be applied to semiconductor element 11 over recessed portion 32.

FIG. 5D is a cross-sectional view taken along line B-B of FIG. 5A, illustrating a cross section including recessed portion 34. As illustrated in FIG. 5A and FIG. 5D, recessed portion 34 extends from under semiconductor element 11 to outside semiconductor element 11. That is, a part of recessed portion 34 is located under semiconductor element 11, and the other part of recessed portion 34 is exposed to a space outside semiconductor element 11. The outgas enters recessed portion 34 and is discharged from recessed portion 34 to the outside air. As illustrated in FIG. 5A, end portion 36 is located outside semiconductor element 11. End portion 35 of recessed portion 34 is located under semiconductor element 11. Since end portion 35 has an arc shape, the outgas is unlikely to be concentrated. As described above, the generation of voids can be suppressed by outgassing countermeasure structure 30.

As illustrated in FIG. 6A and FIG. 6B, substrate 49 is removed by wet etching using, for example, a hydrochloric acid-based etchant. Contact layer 48 serves as an etching stop layer, and the layers from contact layer 48 to damage relaxation layer 40 are not etched.

As illustrated in FIG. 7A and FIG. 7B, the portions of semiconductor element 11 over recessed portion 32 and recessed portion 34 and the like are removed by etching. In detail, an insulating film such as SiN having a thickness of 300 nm is deposited on contact layer 48, and a resist is applied. A resist pattern is formed by photolithography. A pattern is transferred to the insulating film by etching using buffered hydrofluoric acid (BHF) or CF₄ (tetrafluoromethane) and oxygen (O₂). The insulating film is used as a mask to perform reactive ion etching (CH₄/H₂-RIE) using, for example, a methane-hydrogen mixture gas. The mask is removed with BHF. Two semiconductor elements 11 remain on waveguides 22.

As illustrated in FIG. 8A and FIG. 8B, mesa 54, protruding portion 55, and protruding portion 56 are formed in semiconductor element 11. An insulating film and a resist are formed. A resist pattern is formed by photolithography. The pattern is transferred to the insulating film, and CH₄/H₂-RIE is performed using the insulating film as a mask. In the portion not protected by the mask, the layers from contact layer 48 to core layer 44 are removed. Mesa 54, protruding portion 55, and protruding portion 56 are formed in the portions where core layer 44, cladding layer 46, and contact layer 48 remain.

As illustrated in FIG. 9A and FIG. 9B, insulating film 18 is formed to cover semiconductor element 11. Recessed portions 32 and recessed portions 34 are also covered with insulating film 18. A resist pattern is formed by photolithography. The pattern is transferred to insulating film 18. Insulating film 18 on mesa 54 is removed. A portion of insulating film 18 between mesa 54 and protruding portion 56 is removed. Electrode 50 and electrode 52 are formed by vapor deposition and lift-off. Substrate 12 is polished to reduce the thickness of entire substrate 10 to, for example, 150 μm to 350 μm. Silicon wafer 1 is diced to form a plurality of semiconductor optical devices 100.

According to the first embodiment, substrate 10 includes outgassing countermeasure structure 30. Outgassing countermeasure structure 30 includes a portion recessed from surface 61 of silicon layer 16. More specifically, outgassing countermeasure structure 30 includes recessed portion 32 and recessed portion 34. Semiconductor element 11 is disposed over recessed portion 32 and recessed portion 34 and is bonded to silicon layer 16 by thermal treatment. In the thermal treatment, the temperature is increased to, for example, several hundred degrees. The outgas enters outgassing countermeasure structure 30, and thus is unlikely to accumulate at the bonding interface. The generation of voids at the bonding interface can be suppressed. The bonding strength of semiconductor element 11 is increased, and the burst of semiconductor element 11 is suppressed, and the yield is improved.

As illustrated in FIG. 4B, recessed portion 32 is located under semiconductor element 11 and is closed by semiconductor element 11. Since the outgas is confined in recessed portion 32, the generation of voids can be suppressed.

As illustrated in FIG. 2B, the planar shape of recessed portion 32 is ring-shaped, for example, a circular ring shape. Recessed portion 32 includes a curve and does not have a vertex. The outgas is unlikely to be concentrated at one place inside recessed portion 32. Since the internal pressure of recessed portion 32 is unlikely to increase, the generation of voids can be suppressed. The planar shape of recessed portion 32 may be a closed ring or a partially open shape as described below. The planar shape of recessed portion 32 may be other than a circular ring.

As illustrated in FIG. 5D, recessed portion 34 extends from under semiconductor element 11 to outside semiconductor element 11. The outgas is discharged from under semiconductor element 11 to the outside through recessed portion 34. The generation of voids can be suppressed.

As illustrated in FIG. 5A, end portion 35 of recessed portion 34 is located under semiconductor element 11. As illustrated in FIG. 4C, end portion 35 has a curved shape, such as an arc shape, and does not have a vertex. The outgas is unlikely to be concentrated at one place in recessed portion 34, and the internal pressure is unlikely to increase. The generation of voids can be suppressed.

The number and size of recessed portion 32 and recessed portion 34 may be changed. When the area occupied by the recessed portions in the surface of substrate 10 increases, the contact area between semiconductor element 11 and substrate 10 decreases, and the bonding strength may decrease. Recessed portion 32 and recessed portion 34 are large and arranged in large numbers, and thus a large amount of the outgas can be taken into the recessed portions. However, there is a possibility that the outgas leaks from the recessed portions and voids may be generated.

According to the first embodiment, the outgas is confined in recessed portion 32 and re-discharged is suppressed. The width W1 of recessed portion 32 is, for example, 1 μm to 10 μm, and is set to about 5 μm. The diameter D1 of recessed portion 32 is 10 μm to 100 μm, for example, 50 μm. The pitch D2 is, for example, 100 μm to 200 μm.

According to the first embodiment, the outgas is discharged from recessed portion 34 to the outside air, and the generation of voids due to the outgas in recessed portion 34 is suppressed. The width W2 of recessed portion 34 is, for example, 1 μm to 10 μm, and is set to about 5 μm. The pitch P is, for example, 100 μm to 200 μm. Recessed portion 34 may be parallel to the Y-axis or may be inclined with respect to the Y-axis direction. Recessed portion 34 may be straight or may include a curve.

As illustrated in FIG. 5C and FIG. 5D, recessed portion 32 and recessed portion 34 extend partway into silicon layer 16 of substrate 10. The bottom surfaces of recessed portion 32 and recessed portion 34 are formed by silicon layer 16. The outgas is confined in recessed portion 32 and is discharged to the outside air through recessed portion 34. The generation of voids can be suppressed.

### (First Modification)

In a first modification, the depth of recessed portion 32 is changed. FIG. 10 is a cross-sectional view illustrating a method of manufacturing a semiconductor optical device according to the first modification, illustrating the step corresponding to FIG. 5C. Recessed portion 32 penetrates silicon layer 16 and extends partway into box layer 14. A depth D4 from an upper surface of box layer 14 to a bottom surface of recessed portion 32 is, for example, 100 nm. According to the modification, the outgas is confined in recessed portion 32 and absorbed in box layer 14. The generation of voids can be suppressed.

Recessed portion 34 may extend to box layer 14. However, a part of box layer 14 is exposed from silicon layer 16 and is not protected by silicon layer 16. Recessed portion 34 is a structure for releasing the outgas to the outside, and it is important that a part of recessed portion 34 is exposed to the outside semiconductor element 11. The effect of outgas discharge can be obtained whether recessed portion 34 extends to box layer 14 or not. Recessed portion 34 does not penetrate silicon layer 16 and extends partway into silicon layer 16, so that box layer 14 is covered with silicon layer 16 and protected.

### (Second Modification)

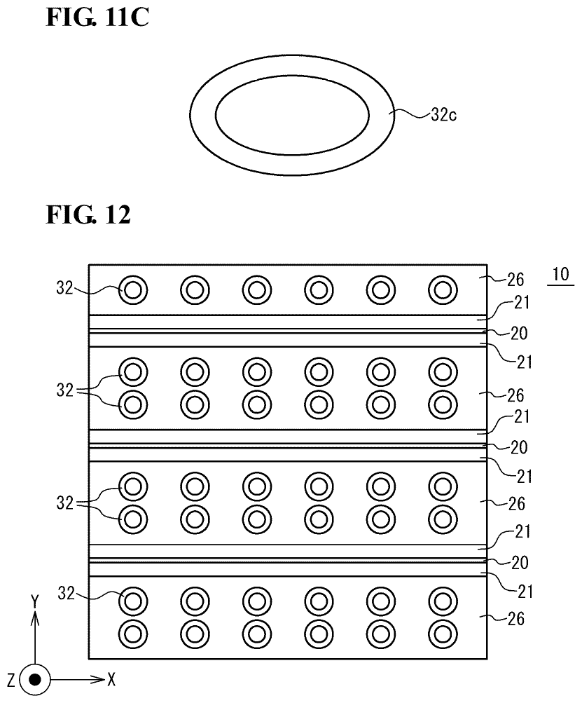

In a second modification, the planar shape of recessed portion 32 is changed. FIG. 11A to FIG. 11C are plan views each illustrating a recessed portion according to the second modification. A recessed portion 32a of FIG. 11A is a partially opened circular ring shape. An angle θ of a chipped portion is larger than 0 degrees and smaller than 360 degrees.

In FIG. 11B, two recessed portions 32b are illustrated. Recessed portions 32b are obtained by dividing circular ring shaped recessed portion 32 into two. Two recessed portions 32b are spaced apart from each other and separated by silicon layer 16. A planar shape of recessed portion 32b is, for example, an arc shape.

As illustrated in FIG. 11C, a planar shape of a recessed portion 32c is elliptical. The flattening ratio is more than zero and one or less.

Any one of recessed portion 32, recessed portion 32a, recessed portion 32b, and recessed portion 32c may be provided in substrate 10 and may be located under semiconductor element 11. The outgas is confined in these recessed portions, and thus the generation of voids is suppressed. The end portions of recessed portion 32a and recessed portion 32b may be curved.

### Second Embodiment

FIG. 12 is a plan view illustrating substrate 10 according to a second embodiment. The description of the same configuration as that of the first embodiment will be omitted.

As illustrated in FIG. 12, substrate 10 does not have recessed portion 34, but has a plurality of recessed portions 32 as an outgassing countermeasure structure. A plurality of waveguides 20 are provided in substrate 10. Recessed portion 21 and terrace 26 are arranged in order on both sides of each waveguide 20. The plurality of recessed portions 32 are provided in terrace 26 and arranged in the X-axis direction. One or two rows of recessed portions 32 are arranged in terrace 26.

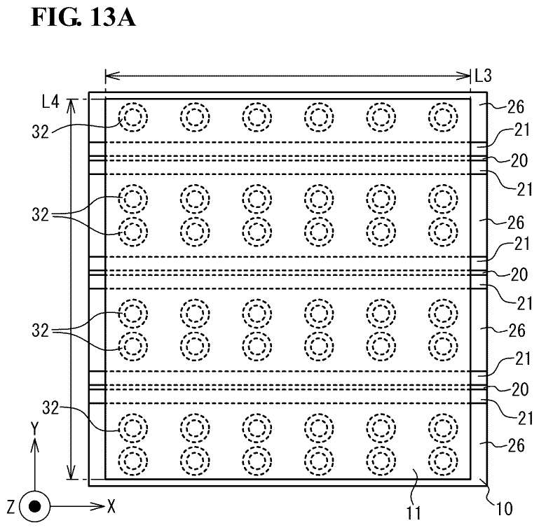

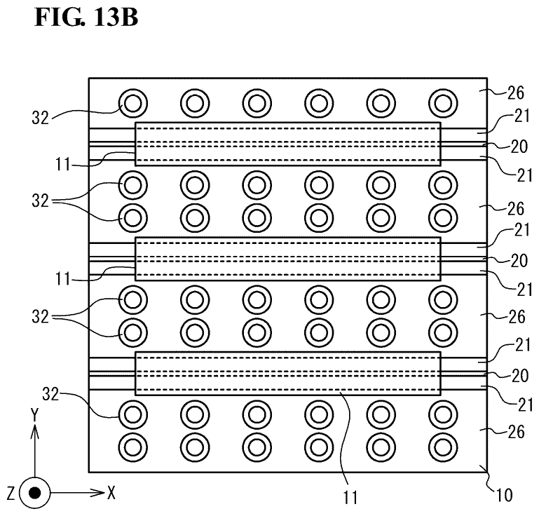

FIG. 13A and FIG. 13B are plan views each illustrating a method of manufacturing a semiconductor optical device. FIG. 13A is illustrating the step corresponding to FIG. 5A. As illustrated in FIG. 13A, semiconductor element 11 is bonded to substrate 10. A planar shape of semiconductor element 11 is a rectangle. A length L3 and a length L4 of semiconductor element 11 are each 2 mm, for example. Semiconductor element 11 is located over three waveguides 20 and is bonded to four terraces 26. The plurality of recessed portions 32 are covered by semiconductor element 11. Outgas generated in the bonding step is confined in recessed portions 32.

As illustrated in FIG. 13B, etching is performed to semiconductor element 11. Semiconductor elements 11 remain over three waveguides 20. Recessed portion 32 is exposed and the outgas is discharged to the outside air. A mesa, an electrode, and the like are formed in three semiconductor elements 11.

According to the second embodiment, substrate 10 has recessed portions 32. Semiconductor elements 11 are disposed over recessed portions 32 and are bonded to silicon layer 16 by thermal treatment. The outgas is confined in recessed portions 32. The generation of voids can be suppressed, and the bonding strength of semiconductor element 11 is increased.

At the time of the bonding, all of the plurality of recessed portions 32 are located under semiconductor elements 11 and are sealed by semiconductor elements 11. The outgas may be confined in the plurality of recessed portions 32. The number and positions of recessed portions 32 may be changed according to the sizes of substrate 10 and semiconductor element 11.

### Third Embodiment

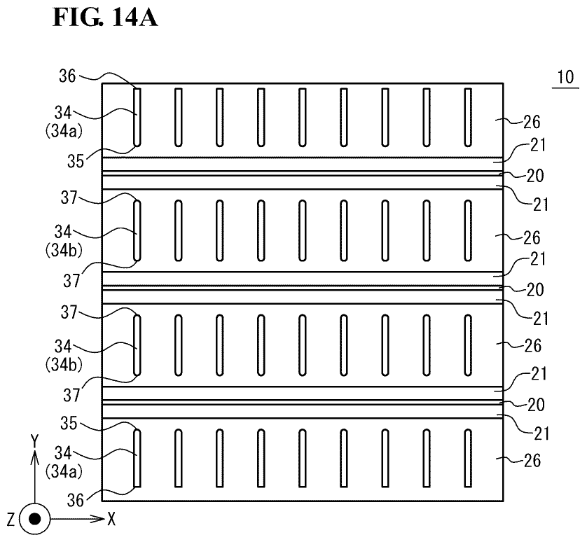

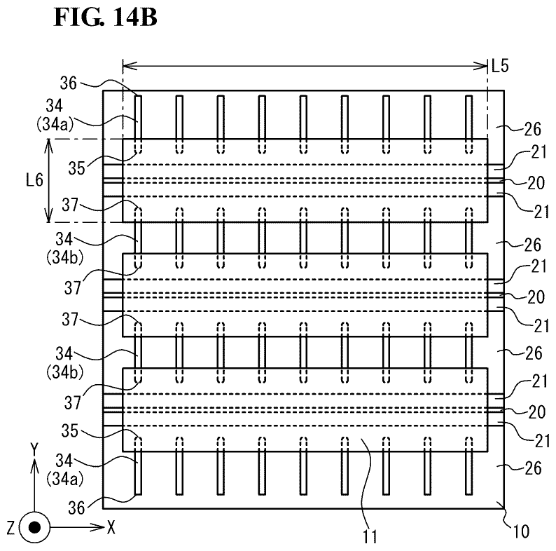

FIG. 14A is a plan view illustrating substrate 10 according to a third embodiment. The description of the same configuration as that of the first embodiment or the second embodiment will be omitted.

As illustrated in FIG. 14A, substrate 10 does not have recessed portion 32, but has a plurality of recessed portions 34 as an outgassing countermeasure structure. The plurality of recessed portions 34 are provided in terrace 26 and arranged in the X-axis direction. One or two rows of recessed portions 34 are arranged in terrace 26. Recessed portions 34 extend in the Y-axis direction.

The plurality of recessed portions 34 include recessed portions 34a and recessed portions 34b. Recessed portion 34a has end portion 35 and end portion 36. End portion 35 faces waveguide 20 and has, for example, an arc shape. End portion 36 is located opposite to end portion 35 and has a vertex. Recessed portion 34b has two end portions 37. End portion 37 faces waveguide 20 and has an arc shape.

FIG. 14B is a plan view illustrating a method of manufacturing a semiconductor optical device, illustrating the step corresponding to FIG. 5A. A plurality of semiconductor elements 11 are manufactured from a wafer of a III-V group compound semiconductor. For example, three semiconductor elements 11 are bonded to substrate 10. One semiconductor element 11 is provided over one waveguide 20. The planar shape of semiconductor element 11 is a rectangle. A length L5 of semiconductor element 11 in the X-axis direction is, for example, 2 mm. A length L6 in the Y-axis direction is, for example, 1 mm.

A part of recessed portion 34 is located under semiconductor element 11, and the other part of recessed portion 34 is exposed outside semiconductor element 11. End portion 35 of recessed portion 34a is located under semiconductor element 11, and end portion 36 of recessed portion 34a is located outside semiconductor element 11. Two end portions 37 of recessed portion 34b are located under semiconductor element 11. A portion between two end portions 37 of recessed portion 34b is located outside semiconductor element 11. Outgas generated in the bonding step is discharged from recessed portions 34 to the outside air.

According to the third embodiment, when semiconductor element 11 is bonded to substrate 10, recessed portion 34 extends from under semiconductor element 11 to outside semiconductor element 11. The outgas is discharged from under semiconductor element 11 to the outside through recessed portion 34. The generation of voids can be suppressed.

The number and positions of recessed portions 34 may be changed according to the sizes of substrate 10 and semiconductor element 11. As illustrated in FIG. 14B, it is only necessary that at least a portion of recessed portion 34 is exposed from semiconductor element 11 at the time of bonding.

Although the embodiments of the present disclosure have been described in detail, the present disclosure is not limited to the specific embodiments, and various modifications and changes can be made within the scope of the gist of the present disclosure described in the claims.

What is claimed is:

1. A method of manufacturing a semiconductor optical device including a substrate having a silicon layer and a semiconductor element having a III-V group compound semiconductor layer,
wherein the silicon layer is provided with a waveguide, a terrace, and an outgassing countermeasure structure, and
the outgassing countermeasure structure includes a portion recessed from an upper surface of the silicon layer, and
wherein the method includes
bringing the semiconductor element into contact with the upper surface of the silicon layer by disposing the semiconductor element over the waveguide and the outgassing countermeasure structure, and
bonding the semiconductor element to the substrate by performing a thermal treatment after the bringing into contact.

2. The method of manufacturing a semiconductor optical device according to claim 1, wherein the outgassing countermeasure structure includes a first recessed portion, and
in the bringing into contact, the first recessed portion is located under the semiconductor element.

3. The method of manufacturing a semiconductor optical device according to claim 2, wherein a planar shape of the first recessed portion is ring-shaped.

4. The method of manufacturing a semiconductor optical device according to claim 2, wherein the planar shape of the first recessed portion includes a curve.

5. The method of manufacturing a semiconductor optical device according to claim 2, wherein the substrate has the silicon layer and a box layer,
the box layer is provided on a surface of the silicon layer opposite to the upper surface, and
a bottom surface of the first recessed portion is formed by the silicon layer or the box layer.

6. The method of manufacturing a semiconductor optical device according to claim 1, wherein the outgassing countermeasure structure includes a second recessed portion, and
in the bringing into contact, a first end portion of the second recessed portion extends from under the semiconductor element to outside the semiconductor element.

7. The method of manufacturing a semiconductor optical device according to claim 6, wherein at least one end portion of the second recessed portion is located under the semiconductor element and has a curved shape.

8. The method of manufacturing a semiconductor optical device according to claim 6, wherein the substrate has the silicon layer and a box layer,
the box layer is provided on a surface of the silicon layer opposite to the upper surface, and
a bottom surface of the second recessed portion is formed by the silicon layer.

9. A semiconductor optical device comprising:
a substrate having a silicon layer; and
a semiconductor element having a III-V group compound semiconductor layer,
wherein the silicon layer is provided with a waveguide, a terrace, and an outgassing countermeasure structure,
the outgassing countermeasure structure includes a portion recessed from an upper surface of the silicon layer, and
the semiconductor element is disposed over the waveguide and the outgassing countermeasure structure and bonded to the upper surface of the silicon layer.
